(19) United States
(12) Patent Application Publication
(10) Pub. No.: US 2024/0379591 A1
(43) Pub. Date: Nov. 14, 2024

(54) SEMICONDUCTOR DEVICE, COMMUNICATION APPARATUS, AND IMAGE CAPTURING SYSTEM

(71) Applicant: CANON KABUSHIKI KAISHA, Tokyo (JP)

(72) Inventors: TATSUYA MURAO, Kanagawa (JP); YASUSHI KOYAMA, Kanagawa (JP); JUN IBA, Kanagawa (JP)

(21) Appl. No.: 18/651,878

(22) Filed: May 1, 2024

(30) Foreign Application Priority Data
May 11, 2023 (JP) 2023-078703

(51) Int. Cl. H01L 23/66; H01L 23/00; H01L 23/373; H01L 23/498; H01L 25/065

(52) U.S. Cl. CPC H01L 23/66; H01L 23/3735; H01L 23/49816; H01L 23/49822; H01L 24/08; H01L 24/16; H01L 25/0652; H01L 2223/6616; H01L 2223/6644; H01L 2224/08145; H01L 2224/08225; H01L 2224/16146; H01L 2224/16227; H01L 2924/01029; H01L 2924/01079; H01L 2924/12043; H01L 2924/13051; H01L 2924/13064; H01L 2924/15311

(57) ABSTRACT

A semiconductor device in which a first structure that includes a first semiconductor substrate on which a semiconductor element and an antenna configured to oscillate or receive an electromagnetic wave are arranged, a second structure that includes a second semiconductor substrate on which a control circuit configured to control the semiconductor element is arranged, and a third structure that has a first bonding surface bonded to the first structure and a second bonding surface bonded to the second structure are stacked, is provided. A first conductor plug electrically connected to the semiconductor element and reaching the first bonding surface is arranged in the first structure, the third structure includes a base material layer and a conductor layer stacked on each other, and the third structure has a higher thermal conductivity than the first structure and the second structure.

### BACKGROUND OF THE INVENTION

### Field of the Invention

The present invention relates to a semiconductor device, a communication apparatus, and an image capturing system.

### Description of the Related Art

For a high frequency region such as a millimeter wave or a terahertz band, the antenna size decreases in accordance with the used wavelength, and the density of peripheral circuits and the like are increased in accordance with the antenna size. Further, since a loss caused by a transmission line increases, a monolithic microwave integrated circuit (MMIC) has been widely developed in which an antenna circuit and a control circuit are stacked to shorten the transmission line, thereby reducing the loss and integrating them into a small package. Japanese Patent Laid-Open No. 2011-097526 describes a millimeter wave wireless apparatus that implements miniaturization by overlapping and arranging a COMS-IC and a patch antenna.

As a higher frequency is used, the circuit density becomes higher and the loss increases, and this increases power consumption and a heat generation amount. Temperature rise of the device due to an increase in heat generation amount can cause a deterioration in operational stability of the device and a shorter element life.

### SUMMARY OF THE INVENTION

Some embodiments of the present invention provide a technique advantageous in suppressing temperature rise of a device.

According to some embodiments, a semiconductor device in which a first structure that includes a first semiconductor substrate on which a semiconductor element and an antenna configured to oscillate or receive an electromagnetic wave are arranged, a second structure that includes a second semiconductor substrate on which a control circuit configured to control the semiconductor element is arranged, and a third structure that has a first bonding surface bonded to the first structure and a second bonding surface bonded to the second structure are stacked, wherein a first conductor plug electrically connected to the semiconductor element and reaching the first bonding surface is arranged in the first structure, the third structure includes a base material layer and a conductor layer stacked on each other, and the third structure has a higher thermal conductivity than the first structure and the second structure, is provided.

Further features of the present invention will become apparent from the following description of exemplary embodiments (with reference to the attached drawings).

### BRIEF DESCRIPTION OF THE DRAWINGS

FIGS. 1A to 1C are sectional views showing an example of the arrangement of a semiconductor device according to an embodiment;

FIGS. 2A to 2C are plan views showing the example of the arrangement of the semiconductor device shown in FIGS. 1A to 1C;

FIGS. 3A to 3D are views showing an example of the arrangement of a pixel of the semiconductor device shown in FIGS. 1A to 1C;

FIG. 4 is a sectional view showing a mounting example of the semiconductor device shown in FIGS. 1A to 1C;

FIG. 5 is a sectional view showing a modification of the semiconductor device shown in FIGS. 1A to 1C;

FIG. 6 is a sectional view showing a modification of the semiconductor device shown in FIGS. 1A to 1C;

FIG. 7 is a sectional view showing a modification of the semiconductor device shown in FIGS. 1A to 1C;

FIG. 8 is a sectional view showing a modification of the semiconductor device shown in FIGS. 1A to 1C;

FIG. 9 is a sectional view showing a modification of the semiconductor device shown in FIGS. 1A to 1C;

FIG. 10 is a sectional view showing a modification of the semiconductor device shown in FIGS. 1A to 1C;

FIGS. 11A to 11C are plan views each showing an example of the arrangement of the semiconductor device shown in FIGS. 1A to 1C;

FIG. 12 is a view showing an example of the configuration of an image capturing system using the semiconductor device shown in FIGS. 1A to 1C; and

FIG. 13 is a view showing an example of the arrangement of a communication apparatus using the semiconductor device shown in FIGS. 1A to 1C.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

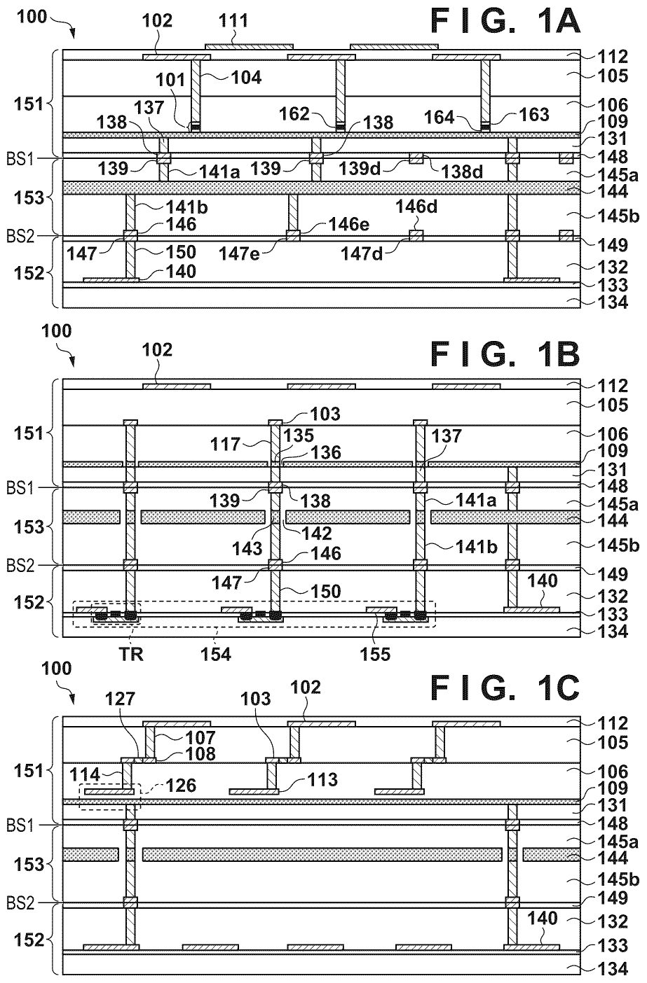

With reference to FIGS. 1A to 13, a semiconductor device according to an embodiment of the present disclosure will be described. In the following description, a case where a semiconductor device 100 according to this embodiment is used as an oscillation apparatus that mainly emits a terahertz wave will be described. However, the present invention is no limited to this, and the semiconductor device 100 can also be used as a detection apparatus that receives a terahertz wave. Here, a terahertz wave indicates an electromagnetic wave within a frequency range of 10 GHZ (inclusive) to 100 THz (inclusive). Alternatively, a terahertz wave may indicate an electromagnetic wave within a frequency range of 30 GHz (inclusive) to 30 THz (inclusive). However, the present invention is not limited to this, and the semiconductor device 100 may be used to oscillate (emit) or receive (detect) an electromagnetic wave of another frequency.

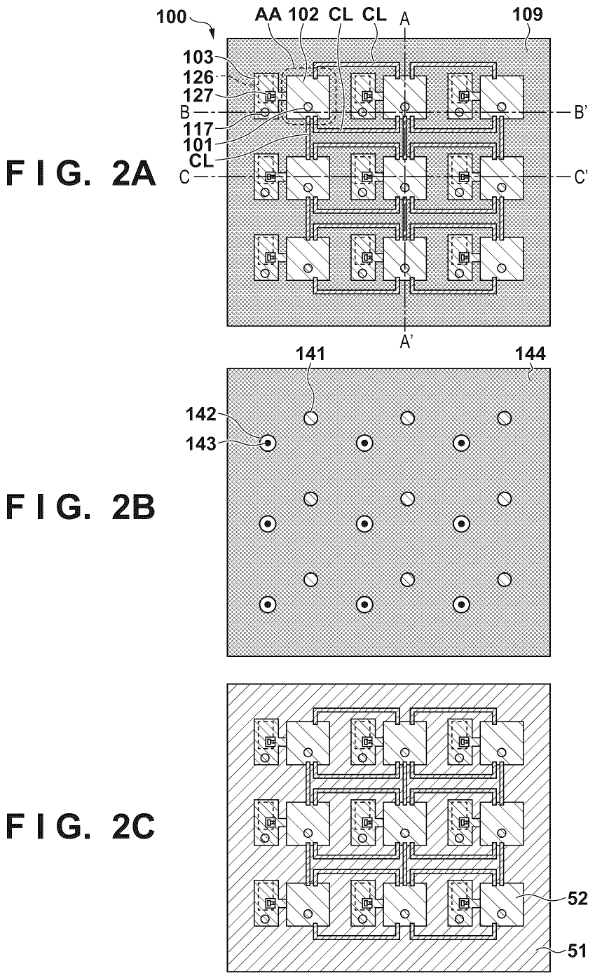

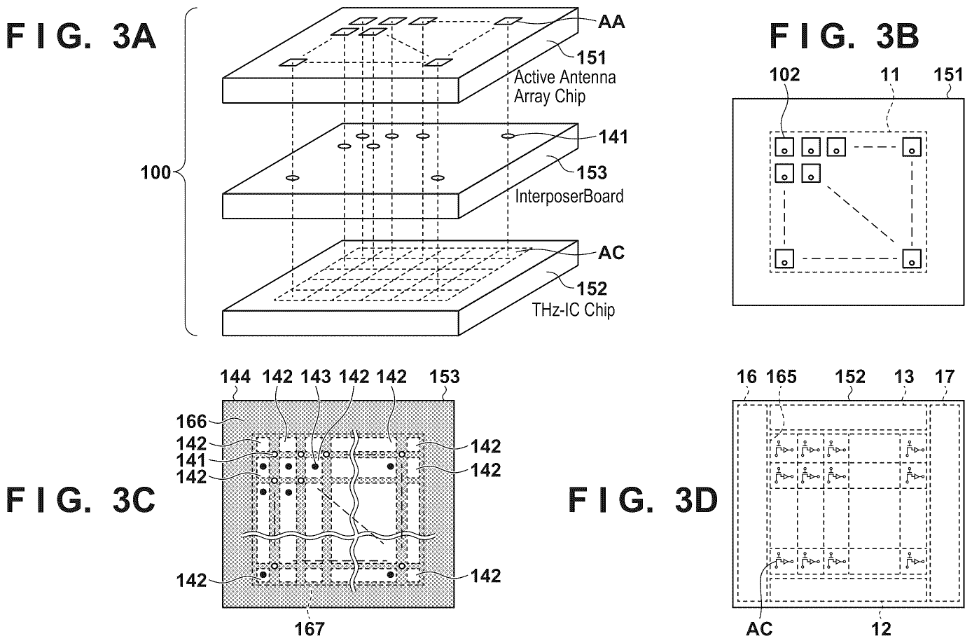

FIGS. 1A to 1C are sectional views of the semiconductor device 100 applicable to an oscillation apparatus that emits a terahertz wave. FIGS. 2A and 2C are plan views of the semiconductor device 100. FIGS. 1A, 1B, and 1C show sections taken along a line A-A′ a line B-B′, and a line C-C′, respectively, of the upper surface of the semiconductor device 100 shown in FIG. 2A. FIGS. 3A to 3D are views for showing an outline of the semiconductor device 100.

As shown in FIGS. 1A to 1C, the semiconductor device 100 is a so-called stacked chip in which a structure 151, a structure 152, and a structure 153 are stacked. The structure 151 includes a semiconductor substrate 131 on which a semiconductor element 101 and an antenna configured to oscillate an electromagnetic wave such as a terahertz wave are arranged. The structure 151 includes an antenna array arranged on the semiconductor substrate 131 of a compound semiconductor substrate, and is sometimes called an antenna board. The structure 152 includes a semiconductor substrate 134 on which a control circuit configured to control the semiconductor element 101 is arranged. The structure 152 is, for example, a silicon integrated circuit board using a silicon substrate as the semiconductor substrate 134. The structure 153 has a bonding surface BS1 bonded to the structure 151 and a bonding surface BS2 bonded to the structure 152. The structure 153 is stacked so as to exist between the structure 151 and the structure 152. The structure 153 is an interposer board made of a material excellent in thermal conductivity and connecting the structure 151 and the structure 152. The semiconductor device 100 is implemented by stacking these three structures 151, 152, and 153 by using a known semiconductor stacking technique.

FIG. 3A is a block diagram showing the conceptual arrangement of the semiconductor device 100 according to this embodiment. FIG. 3B is a schematic view of the structure 151 forming the semiconductor device 100 when viewed from above. FIG. 3C is an example of a schematic view of the structure 153 forming the semiconductor device 100 when viewed from above (for example, the bonding surface BS1). FIG. 3D is a conceptual view of the structure 152 forming the semiconductor device 100 when viewed from above (for example, the bonding surface with the structure 153).

First, an active antenna array 11 formed in the structure 151 will be described. As shown in FIG. 3A, in the structure 151, a plurality of active antennas AA are arranged in an array, thereby forming the active antenna array 11. The active antenna AA includes the semiconductor element 101 used to transmit/receive a terahertz wave, and a conductor pattern 102 serving as an antenna. A wiring layer where the conductor pattern 102 is arranged is also called an antenna layer. The active antenna array 11 indicates an antenna array in which m antennas in the vertical direction and n active antennas in the horizontal direction (m≥1, n≥1) are arranged in an m×n matrix, as shown in FIGS. 3A and 3B. Here, the central portion of the semiconductor device 100 indicates a region which overlaps the region inside the frame surrounding the active antenna array 11 in FIG. 3B, and the outer peripheral portion thereof indicates a region which overlaps the region outside the frame.

The structure 152 includes a control circuit 165 for individually controlling the active antennas AA. The control circuit 165 includes a plurality of control elements AC. In this embodiment, the control elements AC are connected to the active antennas AA in a one-to-one relationship, and can be arranged in a matrix, similar to the active antennas AA. Therefore, the control circuit 165 can be arranged in the central portion of the structure 152. The control element AC arranged in the structure 152 may be arranged in a region immediately below the corresponding active antenna AA arranged in the structure 151. In this case, the wiring length between the corresponding active antenna AA and the control element AC is shortest, and the lengths of wirings that couple the respective active antennas AA to the control elements AC are substantially equal to each other. Hence, it is possible to reduce wiring inductance. The control circuit 165 is an integrated circuit in which an ON/OFF switch of each active antenna AA, a transistor serving as a bias control circuit that supplies a bias signal to the semiconductor element 101, a transistor serving as a phase control circuit that controls the phase of an electromagnetic wave output to the antenna, and the like are arranged. Further, for example, as shown in FIG. 3D, a bias circuit 12, a phase control integrated circuit 13, a baseband integrated circuit 17, an analog-digital conversion circuit/digital-analog conversion circuit 16, and the like, that cooperate with the control circuit 165, may be arranged in the structure 152.

The arrangement of the structure 152 is not limited to the matrix arrangement of the control elements AC shown in FIG. 3D. For example, the arrangement may be employed in which the active antennas AA are controlled on a column basis and a row basis, like a line driving circuit. In this case, a horizontal shift register and a vertical shift register for specifying a column and a row of the control elements AC, respectively, are arranged in the outer peripheral portion of the structure 152. Further, a switch or the like that switches a matrix to be controlled by a signal from the shift register is provided in the control circuit 165. As long as the active antenna AA arranged in the structure 151 can be controlled, the control circuit arranged in the structure 152 can have an appropriate arrangement. When the active antenna AA is used as a detection apparatus that receives an electromagnetic wave such as a terahertz wave, a preamplifier, a low-noise amplifier, a filter circuit, or the like can be arranged in the control circuit 165.

The control circuit 165 can be a transistor-based electronic integrated circuit provided on the semiconductor substrate 134 such as a silicon substrate. Such a silicon (Si) device can form each component of the structure 152 such as the control circuit 165 by optionally using a CMOS process and a FinField-Effect Transistor (FinFET) process. For the structure 152, any electronic integrated circuit, which is a compound semiconductor device that operates in a terahertz wave band, based on transistors of a Silicon Germanium (SiGe)-BiCMOS, SiGe-Heterojunction Bipolar Transistor (HBT), Indium Gallium Arsenide (InGaAs)/Indium Phosphide (InP)-High Electron Mobility Transistor (HEMT), InGaAs/InP-HBT, and Gallium Nitride (GaN)-HEMT can be used. In that case, a compound semiconductor substrate such as an SiGe substrate, an InP substrate, or a GaAs substrate can be used for the semiconductor substrate 134. Here, the BiCMOS is a semiconductor circuit obtained by combining a bipolar circuit and a CMOS circuit. Note that the following embodiments will describe a case where an Si MOSFET (MISFET) is used as the transistor. However, as has been described above, the present invention is not limited to this.

FIG. 3C shows a schematic view of a plane of the structure 153 as the interposer board. The structure 153 is the interposer board that electrically connects the structure 151 and the structure 152 by using a conductor plug extending through a through via. Further, as will be described later, the structure 153 has a role of assisting heat dissipation in the semiconductor device 100. The structure 153 includes base material layers 145a and 145b and a conductor layer 144 stacked on each other. A conductor plug 141 electrically connected to the semiconductor element 101 arranged in the structure 151 is connected to the conductor layer 144. In addition, a plurality of opening portions 142 are arranged in the conductor layer 144. A conductor pattern 143 arranged in the same layer as the conductor layer 144 is arranged in each opening portion 142 and connected to the conductor plug electrically connecting the structure 151 and the structure 152. FIG. 3C shows the rectangular opening portions 142, but the circular opening portions 142 may be formed as shown in FIGS. 2B and 3A. The opening portion 142 indicates a portion of the conductor layer 144 where no conductor other than the conductor pattern 143 is arranged. For example, an insulator such as silicon oxide (SiO), silicon nitride (SiN), or aluminum nitride (AlN) may be embedded in the opening portion 142. The opening portion 142 may have a void.

The conductor layer 144 extends to an outer peripheral portion 166 of the structure 153 and is thermally exposed to the outer edge of the structure 153. The structure 153 has a role of diffusing the heat transmitted to the structure 153 toward the periphery of the structure 153 via the base material layers 145a and 145b and the conductor layer 144. Therefore, the structure 153 is made of a material excellent in thermal conductivity as a whole. For example, a ceramic such as AlN may be used for the base material layer 145 (145a and 145b) of the structure. AlN has a high thermal conductivity of about 150 W/m·K or more. For example, the thermal conductivity of InP used as the semiconductor substrate 131 of the structure 151 is about 68 W/m·K. In addition, the coefficient of thermal expansion of AlN is about 4.6 ppm/K, which is close to the coefficient of thermal expansion of InP, 4.5 ppm/K, so that the influence of thermal expansion or the like on the semiconductor process is small.

However, the material of the base material layer 145 is not limited to a ceramic such as AlN. For example, a carbon-based material such as graphite may be used for the base material layer 145. The thermal conductivity of graphite is about one order of magnitude higher than the thermal conductivity of AlN.

For the conductor layer 144, various kinds of metal materials such as aluminum, copper, and gold can be used. These metal materials also have high thermal conductivities. Hence, heat easily transfers in the structure 153, so that the structure 153 promotes heat dissipation in the semiconductor device 100. For example, the thermal conductivity of the structure 153 as a whole may be 100 W/m·K or more. Furthermore, the thermal conductivity of the structure 153 as a whole may be 150 W/m·K or more. In the structures 151 and 152, materials having relatively low thermal conductivities are often used, such as an interlayer insulating film using silicon oxide or the like for insulating wiring layers. Accordingly, the structure 153 has a higher thermal conductivity than the structures 151 and 152. Thus, the heat generated by the elements arranged in the structure 151 and the structure 152 is dissipated via the structure 153.

The thickness of the structure 153 may be adjusted to be about 100 μm or more and 1 mm or less. For example, the thickness of the conductor layer 144 is about 0.25 μm to 1 μm. Accordingly, the thickness of the base material layer 145 (for example, the total of the base material layer 145a and the base material layer 145b) can be substantially 100 μm or more and 1 mm or less. Since the structure 153 is a substrate for conducting heat, if the structure 153 is made thinner, its sectional area decreases and the thermal resistance increases, resulting in degradation in thermal conductivity. To prevent this, the thickness of the structure 153 may be thicker than the thickness of the semiconductor substrate 131 arranged in the structure 151. By making the structure 153 thicker, the structure 153 having a lower thermal resistance than the structure 151 is implemented, so that the structure 153 may have a thickness of 100 μm or more as has been described above. The base material layer 145 (for example, the total of the base material layer 145a and the base material layer 145b) may have a thickness of 100 μm or more. On the other hand, as the thickness of the structure 153 increases, the diameter of a through via for passing a conductor plug that extends through the structure 153 to electrically connect the structure 151 and the structure 152 can increase. In that case, there is a possibility that the degree of freedom of the wiring region where the wiring pattern is arranged may be reduced in the active antenna AA arranged in the structure 151, the control element AC arranged in the structure 152, or the like. Therefore, the maximum thickness of the structure 153 may be suppressed to about 1 mm. The thickness of the base material layer 145 (for example, the total of the base material layer 145a and the base material layer 145b) may be about 1 mm or less.

FIG. 2A is a view showing the upper surface of the structure 151. FIG. 2B is a view showing the surface of the conductor layer 144 in contact with the base material layer 145a in the structure 153. As shown in FIG. 2A, the conductor pattern 102 used as the antenna is a square patch antenna. In FIG. 2A, nine patch antennas are arranged in a 3×3 matrix. The active antennas AA can be arranged at a pitch (interval) equal to or smaller than the wavelength of the terahertz wave to be oscillated or detected, or a pitch of an integer multiple of the wavelength. The active antenna AA includes at least the conductor pattern 102 (the wiring layer where the conductor pattern 102 is arranged can also be called the antenna layer or upper conductor layer) as the upper conductor of the patch antenna, a conductor layer 109 which is a conductor pattern serving as a GND layer and a reflector layer, and the semiconductor element 101 arranged therebetween. With this arrangement, the active antenna AA emits a terahertz wave of an oscillation frequency fTHz in a direction perpendicular to the main surface of the semiconductor substrate 131.

The semiconductor element 101 forming the active antenna AA includes a semiconductor structure for oscillating or detecting a terahertz wave. The semiconductor element 101 can be a negative resistance element. Here, an example of using a resonant tunneling diode (RTD) will be described. The RTD is a typical semiconductor structure having an electromagnetic wave gain in the frequency band of the terahertz wave, and is also called an active layer. The semiconductor element 101 only needs to be a semiconductor element that oscillates or detects an electromagnetic wave, so that it is not limited to the RTD or active antenna configuration but also includes a semiconductor structure such as a CCD or CMOS image sensor. The bias circuit 12 shown in FIG. 3D is a power supply for controlling a bias signal to be applied to the semiconductor element 101, and is electrically connected to the semiconductor element 101 via the control circuit 165.

The RTD serving as the semiconductor element 101 has an internal parasitic capacitance that changes depending on the area. By adjusting the area, the RTD acts as an element capable of high frequency oscillation in the terahertz band or the like. However, in a case of using the RTD in the terahertz band, the area of the RTD is often small. As the area decreases, the current density increases, and the heat generated during driving of the semiconductor device 100 is locally concentrated. The concentrated heat generated by the RTD due to energization for driving influences electromigration in an electrode portion made of a metal or the like and mechanical stress such as thermal expansion. In addition, this generated heat influences the reliability of components, such as deterioration of the life of the semiconductor device 100 and fluctuation in oscillation performance. Further, the semiconductor device 100 includes, in addition to the structure 151 mounted with the RTD, the structure 152 for controlling the RTD and performing signal processing, and heat is also generated in the structure 152 by driving. By efficiently exhausting the heat generated by driving the structures 151 and 152 of the semiconductor device 100 to the outside of the semiconductor device 100, it is possible to contribute to an improvement in reliability such as improved stability and extended life. That is, the structure 153 serves as the interposer board including a heat exhaust mechanism for dissipating the heat generated in the structures 151 and 152.

It is considered that the plurality of active antennas AA are arranged in an array in the structure 151 for the purpose of increasing the antenna gain of the active antenna array 11. The semiconductor element 101 including the RTD is arranged in each active antenna AA, as described above, and the antenna gain is increased by performing mutual injection locking between the active antennas AA.

The active antennas AA are electrically connected by being coupled by a coupling pattern CL serving as a transmission line. The coupling pattern CL is a microstrip line made of a conductor, and can allow mutual injection locking between the active antennas AA at the frequency fTHz. In the example of the 3×3 array shown in FIG. 2A, in order to synchronize the active antennas AA in the horizontal direction (the lateral direction in FIG. 2A), the active antennas AA adjacent to each other in the horizontal direction are electrically connected by two coupling patterns CL. Further, in order to achieve synchronization in the vertical direction (the longitudinal direction in FIG. 2A), the active antennas AA adjacent to each other in the vertical direction are electrically connected by one coupling pattern CL. To establish synchronization among the plurality of active antennas AA, the coupling patterns CL each coupling the adjacent active antennas AA are required. The active antenna AA and the coupling pattern CL are connected by capacitive coupling. The length of the coupling pattern CL is designed so as to satisfy a phase matching condition in either or both of the lateral direction (magnetic field direction/H direction) and the longitudinal direction (electric field direction/E direction) when the active antennas AA adjacent to each other are connected by the coupling line.

This embodiment is applicable not only to the antenna as described above that emits a horizontally/vertically polarized wave as has been described above, but also to an antenna that emits a circularly polarized wave. For example, by setting the conductor pattern 102 serving as the patch antenna to have a rectangular shape other than a square and forming a notch, it is possible to emit a circularly polarized wave. Alternatively, for example, an antenna that emits a circularly polarized wave, which is different from the patch antenna, may be applied as the conductor pattern 102. In this embodiment, the active antenna array 11 that uses the configuration for synchronizing the active antennas AA by using the coupling patterns CL is shown, but the configuration of the coupling patterns CL is not essential and not limited to this.

In an example, the coupling pattern CL is designed to have such length that the electrical length between the RTDs of the adjacent active antennas AA is equal to an integer multiple of 2π (one wavelength). For example, the coupling pattern CL extending in the horizontal direction has such length that the electrical length between the semiconductor elements 101 between the active antennas AA is equal to 4π. Furthermore, the coupling pattern CL extending in the vertical direction has such length that the electrical length between the semiconductor elements 101 between the active antennas AA is equal to 2π. Here, the electrical length indicates a wiring length considering the propagation speed of a high frequency wave that propagates in the coupling pattern CL. That is, the length of the coupling pattern CL is set based on the wavelength of the electromagnetic wave in the coupling pattern CL. By using this design, the semiconductor elements 101 of the active antennas AA are mutual injection-locked in the positive phase. Here, the error range of the length of the coupling pattern CL may be about ±¼π.

Next, with reference to FIGS. 1A to 1C, the stacked structure of the semiconductor device 100 according to this embodiment will be described. As shown in FIG. 1A, in the semiconductor element 101 arranged in the structure 151, an electrode layer 164, a semiconductor structure 162, and an electrode layer 163 are stacked in this order from the conductor layer 109 side and electrically connected to each other. The semiconductor structure 162 is a semiconductor structure having nonlinearity or an electromagnetic wave gain with respect to a terahertz wave, and an RTD is used in this embodiment as has been described above. Further, the electrode layer 163 and the electrode layer 164 have a structure serving as an electrode layer for connecting contact electrodes (ohmic and Schottky electrodes) above and below the semiconductor structure 162 and conductor patterns arranged in upper and lower wiring layers in order to apply a potential difference or a current to the semiconductor structure 162. The electrode layer 163 and the electrode layer 164 can be made of a metal material (Ti/Pd/Au/Cr/Pt/AuGe/Ni/TiW/Mo/ErAs or the like) known as an ohmic electrode or Schottky electrode, or a semiconductor doped with impurities. For example, the semiconductor device 100 may have a stacked structure such as the semiconductor substrate 131 (InP substrate)/the conductor layer 109 (n⁺-InGaAs)/the electrode layer 164 (n-InGaAs)/the semiconductor structure 162 (AlAs/InGaAs/AlAs)/the electrode layer 163 (n-InGaAs).

As the semiconductor substrate 131 of the structure 151 on which a compound semiconductor is integrated, a semi-insulating InP substrate, which is a compound semiconductor substrate on which a compound semiconductor is crystal-grown, may be used. The InP substrate can have a diameter of, for example, about 4 inches. Here, from the viewpoint of reducing wiring inductance, the thickness of the semiconductor substrate 131 using InP or the like may be 100 μm or less. Further, the semiconductor substrate 131 may be thinned to 10 μm or less. The thickness of the semiconductor substrate 131 can be designed within a range of 1/10 or less of the wavelength of the terahertz wave to be operated. In an example, the thickness of the semiconductor substrate 131 is 1/20 or less of the wavelength of the terahertz wave to be operated.

The structure 151 further includes the conductor pattern 102 serving as the antenna, the semiconductor element 101, the conductor layer 109 (reflector layer), dielectric layers 105 and 106, and a conductor plug 104 connecting the conductor pattern 102 and the semiconductor element 101. In addition, to apply a control signal to the semiconductor element 101, a bias conductor pattern 103, a conductor plug 107, a capacitive element 126 having a metal-insulator-metal (MIM) structure, and a resistance element 127 are connected to the active antenna AA as shown in FIGS. 1B and 1C. The capacitive element 126 is arranged to suppress a low-frequency parasitic oscillation caused by a bias control circuit. The capacitive element 126 uses a structure in which a part of the dielectric layer 106 is sandwiched by a conductor layer 113 and the conductor layer 109 serving as the GND layer. The active antennas AA are electrically connected by the coupling pattern CL using a conductor pattern 111 to establish synchronization between the conductor patterns 102 serving as the antennas at a terahertz frequency.

The lower surface of the structure 151 serving as the antenna board on which the active antenna array 11 and the compound semiconductor are integrated is bonded to the bonding surface BS1 of the structure 153 serving as the interposer board. Further, the bonding surface BS2 of the structure 153 is bonded to the structure 152 serving as the integrated circuit board. Here, “bonding” may be defined that the structure 151 shares the bonding surface BS1 with the structure 153, and the structure 152 shares the bonding surface BS2 with the structure 153.

Each of bonding between the structure 151 and the structure 153 and bonding between the structure 152 and the structure 153 may use metal bonding such as Cu—Cu bonding, insulator bonding such as SiO/SiO bonding, adhesive bonding using an adhesive such as benzocyclobutene (BCB), hybrid bonding as a combination of these, or the like. In a case of adhesive bonding, the adhesive can be included in the structures 151 and 152. Other methods include flip-chip bonding for connection using metal bumps made of a metal such as gold (Au) formed on the substrates. As a bonding process, low-temperature bonding using plasma activation, thermocompression bonding, ultrasonic crimping for flip-chip bonding, or the like is used. Further, for bonding, a method of bonding semiconductor wafers of the same size, a method of bonding semiconductor wafers of different sizes, a method (tiling) of separately bonding a plurality of semiconductor chips to a wafer, or the like is used.

As has been described above, FIGS. 1A, 1B, and 1C are sectional views taken along the line A-A′ the line B-B′, and the line C-C′, respectively, shown in FIG. 2A. In the structure 151, an insulator layer 148, the semiconductor substrate 131, the conductor layer 109, the dielectric layers 106 and 105, and a dielectric layer 112 are stacked in this order from the bonding surface BS1 of the structure 153. In the dielectric layers 106, 105 and 112, the conductor plugs 104 and 107, a conductor plug 117, and the conductor patterns 102, 103, and 111 are arranged. In the active antenna array 11, the mesa structure of the semiconductor element 101 is embedded so as to be surrounded by the dielectric layer 106. In the semiconductor substrate 131, a conductor plug 137 is arranged in a through via formed so as to extend through the semiconductor substrate 131. For the conductor plug 137, copper, gold, tungsten, titanium, or the like is used. The insulator layer 148 and an electrode pattern 138 for bonding the structure 151 and the structure 153 are planarized so as to contact the bonding surface BS1, and a bonding process is performed in a state in which the flat lower surface of the structure 151 and the bonding surface BS1 of the structure 153 are exposed. As the dielectric layers 105 and 106 and the insulator layer 148 arranged in the structure 151, for example, an inorganic insulation material such as silicon oxide, silicon nitride, silicon oxynitride (SiON), carbon-containing silicon oxide (SiOC), silicon carbide (SiC), or the like is used.

FIG. 2C is a view for explaining an antenna region and a peripheral region shown in FIG. 2A. As shown in FIG. 2C, the active antenna array 11 is formed while including an antenna region 52 where the antenna is provided (a region in the conductor pattern 102 serving as the upper conductor of the patch antenna) and a peripheral region 51 outside the antenna region, where the bias wirings and coupling patterns CL are provided. The antenna region 52 indicates a region that overlaps the conductor pattern 102, which is the upper conductor of the patch antenna, in the stacking direction of the structures 151, 152, and 153 shown in FIGS. 3B, 3C, and 3D. The peripheral region 51 indicates a region that does not overlap the conductor pattern 102, which is the upper conductor of the patch antenna, in the stacking direction of the structures 151, 152, and 153. In an example, the peripheral region 51 indicates a region that does not overlap the conductor pattern 102, which is the upper conductor of the patch antenna, and is separated from the conductor pattern 102 by 1/10 or more of the wavelength of the terahertz wave. That is, it can be said that the antenna region 52 is a region including the near field of the terahertz wave, and the peripheral region 51 is a region not including the near field of the terahertz wave.

The structure 153 is a region including the base material layer 145 and the conductor layer 144 as described above, where thermal conductivity is high in the semiconductor device 100. In the arrangement shown in FIGS. 1A to 1C, the structure 153 includes the base material layer 145a arranged between the structure 151 and the conductor layer 144, and the base material layer 145b arranged between the conductor layer 144 and the structure 152. An electrode pattern 139 for bonding with the structure 151 is arranged on the bonding surface BS1 side of the base material layer 145a. The electrode pattern 139 is connected to a conductor plug 141a extending through the base material layer 145a. The base material layer 145a and the electrode pattern 139 are planarized at the bonding surface BS1, and a bonding process is performed in a state in which the flat lower surface of the structure 151 and the bonding surface BS1 of the structure 153 are exposed. Accordingly, it can also be said that the bonding surface BS1 is provided between the conductor layer 109 and the structure 153.

Further, as shown in FIG. 1B, the opening portion 142 is arranged in the conductor layer 144 of the structure 153, and the conductor pattern 143 connected to the conductor plug 141a arranged in the base material layer 145a exists therein. The conductor pattern 143 is connected to a conductor plug 141b arranged in the base material layer 145b, and electrically connects the structure 151 and the structure 152. The conductor pattern 143 can be formed from the conductor layer 144 but is electrically insulated from the conductor layer 144 in the semiconductor device 100.

An electrode pattern 146 for bonding with the structure 152 is arranged on the bonding surface BS2 side of the base material layer 145b. The electrode pattern 146 is connected to the conductor plug 141b extending through the base material layer 145b. The base material layer 145b and the electrode pattern 146 are planarized at the bonding surface BS2, and a bonding process is performed in a state in which the flat upper surface of the structure 152 and the bonding surface BS2 of the structure 153 are exposed.

In the structure 152, an insulator layer 133, a conductor pattern 140, an insulator layer 132, and the insulator layer 149 are stacked in this order from the semiconductor substrate 134. A conductor plug 150 is formed in the insulator layer 132, and an electrode pattern 147 for bonding with the structure 153 is formed in the insulator layer 149. The insulator layer 149 and the electrode pattern 147 for bonding the structure 152 and the structure 153 are planarized so as to contact the bonding surface BS2, and a bonding process is performed in a state in which the flat upper surface of the structure 152 and the bonding surface BS2 of the structure 153 are exposed. In the arrangement shown in FIGS. 1A to 1C, the conductor pattern 102 serving as the antenna arranged in the structure 151 is separated from the control circuit 165 arranged in the structure 152. Accordingly, it is possible to reduce noise caused by radio wave interference between the active antenna array 11 that operates at a terahertz frequency and each circuit such as the control circuit 165 that operates at an RF frequency. As the insulator layers 132, 133, and 149, an inorganic insulation material such as silicon oxide, silicon nitride, silicon oxynitride, carbon-containing silicon oxide, silicon carbide, or the like can be used.

The conductor layer 109 serving as a reflector in the structure 151 integrated with the compound semiconductor is electrically connected to the bonding surface BS1 of the structure 153 via the conductor plug 137 provided in the semiconductor substrate 131 and the bonding electrode pattern 138. Here, if the conductor plug 137 and the electrode pattern 138 are defined as a conductor plug as one member arranged in the structure 151, it can also be said that the conductor plug electrically connected to the semiconductor element 101 and reaching the bonding surface BS1 of the structure 153 is arranged in the structure 151. The conductor plug 141a and the bonding electrode pattern 139 arranged in the base material layer 145a are arranged between the conductor layer 144 and the bonding surface BS1 of the structure 153. The electrode pattern 138 and the electrode pattern 139 are electrically connected at the bonding surface BS1. With this, the potential of the conductor layer 109 arranged in the structure 151 and the potential of the conductor layer 144 arranged in the structure 153 are shared. Here, if the conductor plug 137, the electrode pattern 138, the electrode pattern 139, and the conductor plug 141a are defined as a conductor plug as one member arranged in the structures 151 and 153, it can also be said that the conductor plug electrically connected to the semiconductor element 101 and reaching the bonding surface BS1 of the structure 153 further extends through the base material layer 145a and is electrically connected to the conductor layer 144.

To enhance the bonding strength between the structure 151 and the structure 153, dummy electrode patterns 138d and 139d, which do not send/receive signals between the structure 151 and the structure 152, may be arranged on the bonding surface BS1. By widely arranging the dummy electrode patterns 138d and 139d in a region where the electrode patterns 138 and 139 used to send/receive signals between the structure 151 and the structure 152 are unnecessary, the bonding strength in a case of metal bonding can be increased, and yield and reliability can be improved.

The conductor layer 144 of the structure 153 and the conductor pattern 140 of the structure 152 are electrically connected via the conductor plug 141b and the electrode pattern 146 arranged in the base material layer 145b, the conductor plug 150 arranged in the insulator layer 132, and the electrode pattern 147. With this, potentials are shared between the structure 151 and the structure 152. As an example, the conductor pattern 140 of the structure 152 serves as a GND layer, and the GND potential of the entire semiconductor device 100 can be shared.

To enhance the bonding strength between the structure 152 and the structure 153, similar to above, dummy electrode patterns 146d, 146e, 147d, 147e, and the like may be provided on the bonding surface BS2. Further, as shown in FIG. 1A, the dummy electrode pattern 146e may be electrically connected to the conductor layer 144. These dummy electrode patterns are used, as appropriate, as members for efficiently transferring the heat generated in the structure 151 and the structure 152 to the structure 153. In addition, these components can reduce the influence of electromagnetic wave noise on the active antenna AA in the structure 151, which is caused by the integrated circuit of the structure 152.

The structure 151 includes the wiring layer where the conductor pattern 102 serving as the antenna is arranged, and the conductor layer 109 which is a wiring layer arranged between the structure 153 and the wiring layer where the conductor pattern 102 is arranged. As has been described above, the conductor pattern 102 is electrically connected to the semiconductor element 101. The conductor layer 109 is a conductor pattern having a larger area than the conductor pattern 102 in an orthogonal projection with respect to the bonding surface BS1 and electrically connected to the semiconductor element 101. With this arrangement, the conductor pattern 102 and the conductor layer 109 operating as the GND layer function as a patch antenna that resonates with the terahertz wave. In addition to the conductor layer 109 serving as the GND layer and the reflector layer, the conductor pattern 140 arranged in the structure 152 also serves as a GND pattern. Furthermore, the conductor layer 144 can be arranged as an GND layer between the two GND layers/GND patterns. With this, it is possible to reduce noise caused by radio wave interference between the active antenna array 11 that operates at a terahertz frequency and the integrated circuit arranged in the structure 152 such as the control circuit 165 that operates at an RF frequency. To increase the effect of noise reduction, each of the conductor layers 109 and 144 and the conductor pattern 140 serving as the GND layers/GND patterns may be formed in a solid pattern that covers a large area of corresponding one of the semiconductor layer 131, the base material layer 145, and the semiconductor layer 134. The conductor pattern 111 including the coupling pattern CL of the structure 151 is formed on the dielectric layer 112, and electrically connects the conductor patterns 102 as the upper conductors of the antennas.

The conductor pattern 103 forming a bias wiring pattern connected to the semiconductor element 101 of the structure 151 is electrically connected to a transistor TR forming a bias control circuit provided in an integrated circuit arranged in the structure 152. Each transistor TR is formed near the surface of the semiconductor substrate 134 serving as the base material of the structure 152 to form each integrated circuit, other than the bias control circuit, arranged in the structure 152. The conductor pattern 103 is electrically connected to the conductor plug 117 arranged in the dielectric layer 106, a conductor pattern 135 provided in an opening portion 136 of the conductor layer 109, the conductor plug 137 arranged in the semiconductor substrate 131, and the bonding electrode pattern 138 in this order, and reaches the bonding surface BS1. Similarly, the transistor TR arranged in the structure 152 is electrically connected to the conductor plug 150 arranged in the insulator layer 132, and the bonding electrode pattern 147 in this order, and reaches the bonding surface BS2. In the structure 153, the conductor plug 141a and the bonding electrode pattern 139 are electrically connected from the conductor pattern 143 arranged in the opening portion 142 provided in the conductor layer 144 to the bonding surface BS1. In addition, the conductor plug 141b and the bonding electrode pattern 146 are electrically connected from the conductor pattern 143 to the bonding surface BS2. Thus, in the structure 153, the electrode pattern 139 arranged on the bonding surface BS1 and the electrode pattern 146 arranged on the bonding surface BS2 are electrically connected. Further, the electrode pattern 138 arranged in the structure 151 and the electrode pattern 139 arranged in the structure 153 are electrically connected, and the electrode pattern 146 arranged in the structure 153 and the electrode pattern 147 arranged in the structure 152 are electrically connected. With this, the electrode pattern 138 of the structure 151 and the electrode pattern 147 of the structure 152 can be electrically connected. Thus, the bias conductor pattern 103 of the active antenna AA and the transistor TR arranged in the structure 152 are rendered conductive, and bias control of each active antenna AA can be performed. In FIG. 1B, the conductor plug 141a and the conductor plug 141b are arranged at the same position in the orthogonal projection with respect to the bonding surface BS1, but they may be arranged at different positions via the conductor pattern 143. With this, the wiring path from the structure 152 to the structure 151 is extended, and transfer of heat from the structure 152 to the structure 151 can be suppressed.

Here, by devising the arrangement of the opening portion 136 and the respective conductors (the conductor pattern 135, the conductor plug 137, and the electrode pattern 138) electrically connecting the structure 151 and the structure 153, the radiation efficiency and the effect of measures against noise are expected. More specifically, the opening portion 136 provided in the conductor layer 109 serving as the reflector may be arranged in the peripheral region 51 which does not overlap the antenna region 52. However, such the arrangement is not always necessary. For example, if the widths of the conductor pattern 135 and the conductor plug 137 are sufficiently small (typically, 1/10 or less of an electrical length 2) as compared with the electrical length of an electromagnetic wave expected to propagate to the opening portion 136, the conductor pattern 135, and the conductor plug 137, the influence on the active antenna AA is negligible. In this case, the opening portion 136, the conductor pattern 135, and the conductor plug 137 may be arranged in the antenna region 52.

As shown in FIG. 1C, the conductor pattern 102 is electrically connected to a wiring pattern 108 via the conductor plug 107. The wiring pattern 108 is connected to the conductor pattern 103 via the resistance element 127, and further electrically connected to a conductor plug 114 connected to the capacitive element 126. The position of the conductor plug 107 connected to the conductor pattern 102 serving as the antenna is set so as to be connected to the active antenna AA at the position of the node of a resonant electric field formed on the active antenna AA. Further, the conductor pattern 103 described above is a pattern that supplies a bias to the semiconductor element 101, and it can be said that the resistance element 127 and the capacitive element 126 are connected to the bias line. With this, a high frequency other than the frequency fTHz is AC short-circuited, and an impedance at the high frequency is reduced. Thus, the effect of suppressing multi-mode oscillation in the active antenna array 11 can be expected.

As shown in FIG. 1C, a path connected to the conductor pattern 140 serving as the GND layer is shown in the structure 152. In FIG. 1A, the conductor pattern 140 and the conductor layer 144 in the structure 153 are electrically connected. However, in another location in the semiconductor device 100, as shown in FIG. 1C, the conductor pattern 140 may be directly connected to the conductor layer 109 serving as the GND layer in the structure 151 via the conductor pattern 143 arranged in the opening portion 142 provided in the conductor layer 144 of the structure 153. These arrangements are set, as appropriate, when deciding parameters for heat transfer, wiring impedance control, and the like, and are not limited to those described above.

The active antenna AA serves as a resonator that causes an electromagnetic wave such as a terahertz wave to resonate and a radiator that oscillates or detects the electromagnetic wave. The active antenna AA includes the conductor plug 104 for connecting the conductor pattern 102 and the semiconductor element 101, and the coupling pattern CL. The conductor pattern 103 forming the bias wiring is connected to the conductor pattern 102 via the conductor plug 107. The resistance element 127 forming an AC short circuit, the capacitive element 126, and the bias supply conductor plug 117 leading to the structure 152 are connected to the conductor pattern 103. It can also be said that the conductor plug 117 is arranged to electrically connect the integrated circuit arranged in the structure 152 to the conductor pattern 103 arranged in the wiring layer between the wiring layer where the conductor pattern 102 is arranged and the wiring layer where the conductor layer 109 is arranged. As shown in FIG. 1B, the conductor pattern 102 and the conductor plug 117 can be arranged so as not to overlap in the orthogonal projection with respect to the bonding surface BS1.

The conductor plug 141a in the structure 153 electrically and thermally connects the conductor layer 144 and the conductor layer 109 serving as the GND layer in the structure 151. The heat generated from the semiconductor element 101 mainly flows to the structure 153 via the conductor layer 109 serving as the GND layer, the conductor plug 137, and the electrode pattern 138 in the structure 151. The heat further flows to the conductor layer 144 via the electrode pattern 139 and the conductor plug 141a. Hence, the width of the conductor plug 141a connected to the conductor layer 144 for exhausting heat may be set larger that of the width of the conductor plug 141a connected to the conductor pattern 143 of the structure 153. The heat flowing to the structure 153 transfers from the center of the structure 153 to the outer edge where temperature is low, and is dissipated to the outside of the semiconductor device 100. The semiconductor device 100 can operate such that, in a thermal equilibrium state during operation of the semiconductor device 100, the temperature of the structure 153 has a gradient that decreases from the center of the structure 153 toward the outer edge in the orthogonal projection with respect to the bonding surface BS1. When the base material layers 145a and 145b forming the structure 153 are also formed using a material such as aluminum nitride or graphene having a high thermal conductivity, more smooth transfer of heat is possible.

Furthermore, the conductor pattern 143 of the structure 153 is arranged in the opening portion 142 of the conductor layer 144 and electrically insulated from the conductor layer 144. It is possible to form the opening portion 142 in the conductor layer 144 and arrange an electrical path between the structure 151 and the structure 152 therein, as needed. In this case, as shown in FIGS. 3B and 3C, in a region 167 of the conductor layer 144 which overlaps the active antenna array 11, wiring lines (conductor layer 144) running vertically and horizontally may be formed and each opening portion 142 may be provided in the space between the wiring lines. The vertical and horizontal wiring lines of the conductor layer 144 may be arranged over the entire conductor layer 144, and the pattern arrangement of the conductor layer 144 is not limited to that shown in FIGS. 2B and 3C. By improving the thermal conductivity of the base material layer 145 of the structure 153, the conductor layer 144 which is a relatively thin layer and having a high thermal resistance can have small influence on thermal conduction. Therefore, the conductor layer 144 only needs to have an appropriate pattern arrangement in accordance with not only thermal conduction but also the function of the conductor layer 144 as the GND layer and the electrical path between the structure 151 and the structure 152.

Further, for example, a thermal insulating layer having a high thermal resistance may be provided between the semiconductor substrate 134 of the structure 152 and the bonding surface BS2 of the structure 153 to prevent transfer of heat from the structure 152 to the structure 153. The thermal insulating layer can be, for example, a layer having a thermal conductivity of less than 1 W/m·K, which is lower than the thermal conductivity of silicon oxide or the like. Further, for example, in the layer arranged in each of the structures 151 and 152, to balance a temperature drop due to heat dissipation and a temperature rise during driving, a heat storage layer using a material or structure with a large heat capacity may be arranged for the purpose of stabilizing the temperature while maintaining a predetermined temperature. The heat storage layer can be, for example, a layer having a specific heat of 0.9 kJ/kg·K or more, which is higher than the specific heat of silicon oxide or the like.

The semiconductor device 100 including the active antenna AA as shown in FIG. 2A can emit, for example, an electromagnetic wave in a frequency band of 0.3 to 0.6 THz, and the plurality of active antennas AA are capable of signal mode oscillation in the same frequency band. The semiconductor substrate 131 is, for example, a semi-insulating InP substrate. As has been described above, the semiconductor structure 162 of the semiconductor element 101 is formed from a multiquantum well structure by InGaAs/AlAs lattice-matched on the semiconductor substrate 131, and an RTD having a double-barrier structure may be used. This is also called the semiconductor heterostructure of the RTD. In an example, as the current-voltage characteristic of the RTD, the peak current density is 9 mA/μm², and the negative differential conductance per unit area is 10 mS/μm². The semiconductor element 101 may be formed in, for example, a mesa structure. The active antenna AA is a square patch antenna in which one side of the conductor pattern 102 serving as the upper conductor is, for example, 150 μm, and the resonator length (L) of the antenna is 150 μm. The semiconductor element 101 is arranged between the conductor pattern 102 and the conductor layer 109 at a position overlapping the conductor pattern 102.

The width of the conductor plug 104 connecting the semiconductor element 101 and the conductor pattern 102 serving as the antenna can be a width that does not interfere with a resonant electric field. Typically, the width of the conductor plug 104 is set to 1/10 or less of the oscillation frequency fTHz of the active antenna AA. It can also be said that the width of the conductor plug 104 is 1/10 or less of the wavelength of the electromagnetic wave to be oscillated or received by the antenna. Here, the width of the conductor plug 104 is the length of the longest portion in the orthogonal projection with respect to the bonding surface BS1. When the conductor plug 104 has a columnar structure, the width of the conductor plug 104 can be the diameter of the columnar structure. When the conductor plug 104 has a rectangular parallelepiped shape, the width can be the length of the diagonal line. The width of the conductor plug 104 may be small to the extent that series resistance is not increased, and can be reduced to about twice a skin depth as a guide. Considering that the series resistance is decreased to a value not exceeding 1Ω, the width of the conductor plug 104 may typically fall within the range of 0.1 μm (inclusive) to 20 μm (inclusive). In an example, the conductor plug 104 has a columnar structure with a diameter of 10 μm. The same applies to the conductor plugs 107, 114, 137, and the like.

Power necessary for driving the semiconductor element 101 to emit a terahertz wave having a radiation intensity of about 10 mW is about 1 W, based on the bias voltage applied to the semiconductor element 101 and the current flowing therethrough. Since the radiation efficiency is about 1% and ideally about a few percent, the remaining 90% or more is mainly converted into heat and consumed in the structure 151. Accordingly, the structure 151 generates heat, and the amount of heat is 0.9 W or the like. In order to stably drive the structure 151, the semiconductor device 100 of the present disclosure needs to continuously dissipate the heat source of 0.9 W or the like to the outside of the semiconductor device 100, thereby appropriately controlling the temperature of the semiconductor element 101. However, even if a high-performance heat dissipation member is used outside the chip, if the thermal resistance in the thermal path from the semiconductor element 101 inside the semiconductor device 100 to the outside of the semiconductor device 100 is high, the transfer of heat is inhibited, and it becomes difficult to lower the temperature of the semiconductor element 101. Therefore, a configuration for efficiently transferring heat inside the semiconductor device 100 is required.

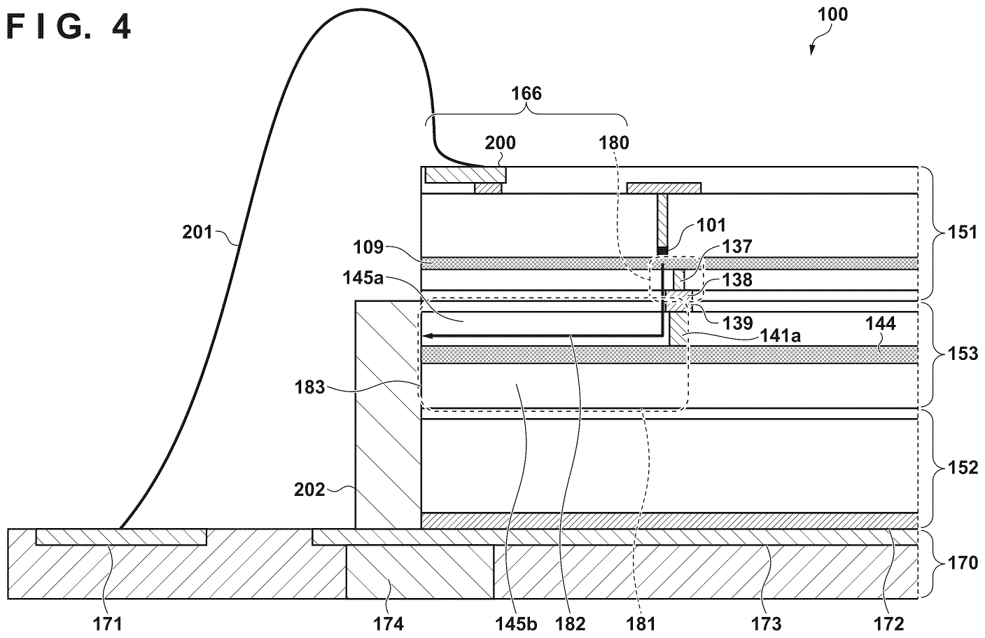

Implementation of the semiconductor device 100 and a main thermal path associated with heat transfer in this embodiment will be described with reference to FIG. 4. FIG. 4 is a schematic view showing the connection form among the structures 151, 153, and 152 and a support substrate 170 (which can be a package substrate, a circuit board, or the like) while focusing on the outer peripheral portion 166 of the semiconductor device 100 (structure 153) shown in FIG. 3C.

The active antenna AA is formed in the surface of the structure 151 and transmits/receives a terahertz wave. In the surface layer of the outer peripheral portion 166 of the structure 151, a PAD portion 200 where a plurality of wire bonding electrodes are arranged is provided. The PAD portion is used to send/receive power and signals that require external control among signals necessary for the circuits arranged in the structure 151 and the structure 152. The electrode arranged in the PAD portion 200 is electrically connected to an electrode pad 171 of the support substrate 170 by a bonding wire 201. A metal such as gold (Au) is used for the bonding wire 201. The structures 151, 153, and 152 are fixed (die-bonded) to the support substrate 170 using a metal adhesive layer 172 applied on at least one of the lower surface of the structure 152 and the support substrate 170. Not only a metal but also a resin or the like may be used for the adhesive layer 172. A metal pad 173 for die bonding is formed in the surface of the support substrate 170 in contact with the adhesive layer 172, and is thermally connected to the structure 152.

Furthermore, a heat dissipator 202 thermally connected to the structure 153 is arranged on the support substrate 170. More specifically, the heat dissipator 202 is in contact with the outer edge of the structure 153. The heat dissipator 202 can be made of a conductor having a high thermal conductivity such as solder or a metal workpiece. The heat dissipator 202 is fixed to the metal pad 173 in the surface of the support substrate 170 and is thermally connected to the support substrate 170. Further, a heat dissipator 174 made of a conductor such as a metal is arranged inside the support substrate 170. The heat dissipator 174 has a role of transmitting the heat of the heat dissipator 202 to a region of the support substrate 170 away from the structures 151, 153, and 152, for example, to the back surface side of the support substrate 170 opposite to the surface facing the structure 152. Thus, the heat can be transmitted from the outer edge (outer peripheral portion 166) of the structure 153 to the outside of the structure 153 and dissipated from the support substrate 170. The heat dissipator 202 may be arranged closer to the support substrate 170 than the conductor pattern 102 serving as the antenna so as not to influence transmission and reception of an electromagnetic wave by the structure 151.

The heat generated in the semiconductor element 101 of the structure 151 along with driving is transmitted through the respective elements of the structure 151 and diffused. However, each of the dielectric layers 105 and 106 and the semiconductor substrate 131 has a lower thermal conductivity than the conductor layer 109 and the conductor plug 137. Accordingly, the heat generated in the semiconductor element 101 is transmitted downward in FIG. 4 to the structure 153 by passing a thermal path 180 mainly including the conductor layer 109, the conductor plug 137, and the electrode pattern 138. The thermal path 180 is connected to a thermal path 181 including the base material layers 145a and 145b and the conductor layer 144, each having a high thermal conductivity in the structure 153. The thermal path 181 extends in a direction from the center of the structure toward the outer edge, that intersects the thickness direction of the structure 153, that is, extends to the left in FIG. 4. The thermal path 181 extends to the outer edge of the outer peripheral portion 166 of the structure 153 and is thermally exposed at an exposure portion 183. The exposure portion 183 may be formed to be exposed over the entire periphery of the outer edge of the structure 153, or may be formed to be exposed only partially. The exposed exposure portion 183 is thermally connected to the heat dissipator 202. An arrow 182 in FIG. 4 indicates a thermal path through which the heat generated in the semiconductor element 101 is transmitted to the outside of the structures 151, 153, and 152. The structure allows the heat generated in the semiconductor element 101 to be mainly transmitted from the thermal path 180 to the thermal path 181 and reach the exposure portion 183, thereby efficiently dissipating the heat of the semiconductor element 101. On the other hand, the current for driving the semiconductor element 101 flows from the structure 152 to the structure 151 via the structure 153, that is, in the vertical direction in FIG. 4. That is, in the structure 153, the heat mainly flows in the horizontal direction in FIG. 4 while the current flows in the vertical direction.

In the active antenna array 11 that oscillates or receives an electromagnetic wave such as a terahertz wave, to individually control each active antenna AA, a plurality of electrical paths are required, such as a bias line for supplying a bias to the semiconductor element 101, the coupling pattern CL for controlling synchronization between the active antennas AA, and a control line for injecting a baseband signal to the active antennas AA. On the other hand, to improve the antenna gain, it is necessary to increase the number of antennas. However, wiring inductance caused by the layout increases along with an increase in number of the active antennas AA, thereby interfering with implementation of a high frequency. To the contrary, in this embodiment, the structure 151 including the active antenna array 11, the structure 153, and the structure 152 as the integrated circuit board for controlling the active antenna array 11 are stacked by a semiconductor bonding technique. This eliminates the necessity to take an implementation form in which peripheral circuits necessary for controlling the active antenna array 11 are integrated on the semiconductor substrate 131 of the structure 151 or connected from outside the semiconductor device 100. This can suppress an increase in inductance caused by routing of the wiring pattern (electrical path), and typically suppress inductance to 1 nH or less, thereby suppressing a signal loss or signal delay of the baseband signal subjected to modulation control at a high frequency of 1 GHz or more. A signal loss in the structure 151 is mainly converted into heat, and this leads to heat generation inside the structure 151. Reducing a signal loss by stacking the structures leads to decreasing the loss of signals and suppressing heat generation.

Furthermore, by stacking the structure 151 and the structure 152, the number of circuits unrelated to terahertz wave transmission/reception can decreased to be zero or sufficiently small in the periphery of the active antenna AA. Accordingly, noise caused by circuits unrelated to terahertz wave transmission/reception is reduced, thereby making it possible to maximize the characteristic of the antenna. If the bias signal of the semiconductor element 101 and the like are controlled for each active antenna AA, a bias line corresponding to each active antenna AA needs to be individually arranged. To the contrary, in this embodiment, the structure 151 including the active antenna array 11 can be directly connected to the integrated circuit arranged in the structure 152 via the conductor plugs (conductor plug 137 and the like) and the structure 153. In a case of using the active antenna array 11, an electrical path such as the conductor plug 137 can be arranged closer to the structure 152 than the conductor layer 109 serving as the reflector. Therefore, it is possible to increase the number of the active antennas AA included in the active antenna array 11 without receiving the influence of the layout. Since the degree of freedom in layout improves, appropriate clearance for the signal transmission line can be ensured, and a loss in the transmission line can be suppressed. That is, this leads to suppressing heat generation caused by the loss.

The shape of the antenna such as the conductor pattern 102 formed in the structure 151 and the semiconductor structure 162 of the semiconductor element 101 are changed as appropriate in accordance with the wavelength of the terahertz wave to be transmitted/received. It is also conceivable that a plurality of kinds of the shapes and structures exist to cover a variety of frequencies. Further, in the structure 152 including the integrated circuit, complex circuits such as the detection circuit and the signal processing circuit can be formed using a conventional CMOS integrated circuit technique. Many circuits such as the signal processing circuit can be used for general purposes regardless of the frequency. In the structure 153, not only connection of the structure 151 and the structure 152 by simple wiring but also connection of the structure 151 arranged with a plurality of kinds of active antennas AA and the general-purpose structure 152 is performed. The structure 153 is optimized to increase the reusability of configuration and design as an intermediate buffer layer that can accommodate diversifying variations and for which it is possible to appropriately perform wiring.

The structures 151, 152, and 153 formed as described above are also advantageous in heat dissipation of the semiconductor device 100 in which the structures 151, 152, and 153 are stacked. When the heat generated in the semiconductor element 101 of the structure 151 spreads throughout the structures 151, 153, and 152, the heat is mainly transmitted to the structure 153 via the electrically conductive conductor plug 137 and conductor layer 109 each having a high thermal conductivity (the thermal path 180 described above). Further, the heat flowing from the thermal path 180 into the structure 153 is thermally connected to the thermal path 181 that transfers heat horizontally (in a direction intersecting the stacking direction of the structures 151, 153, and 152) in the structure 153 having a higher thermal conductivity than the structure 151. The heat of the structure 153 is dissipated from the exposure portion 183 exposed at the outer peripheral portion 166 of the structure 153. The exposure portion 183 may be connected to the heat dissipator 202 as described above. The heat transferred to the heat dissipator 202 may be cooled by a cooling unit that performs heat exchange using a heat sink, a fan, a Peltier element, or the like. The heat generated by the semiconductor element 101 is continuously exhausted via the thermal path 180 and the thermal path 181 by a thermal gradient continuing to the outside of the structures 151, 153, and 152, and the structures 151, 153, and 152 are thus cooled. With this, temperature rise of the semiconductor element 101 can be suppressed, and the stabilized operation and the extended life of the element can be implemented.

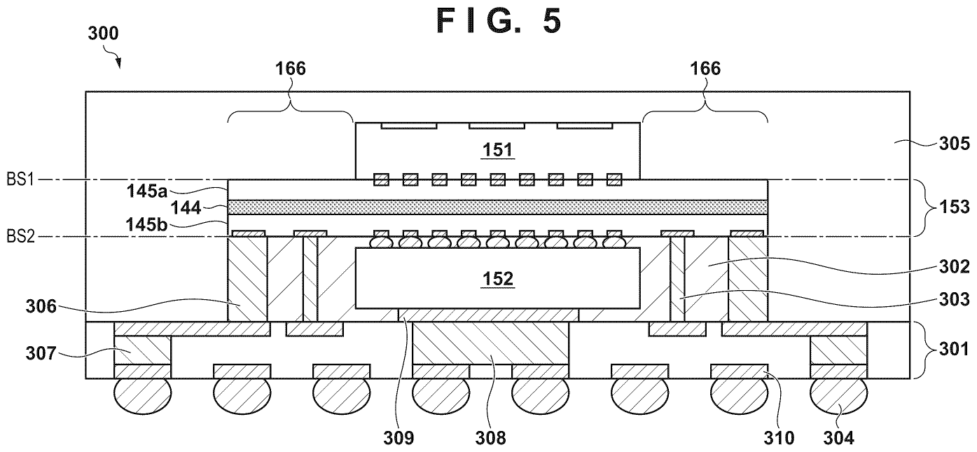

As an embodiment with the present disclosure applied thereto, an example of a semiconductor device 300 of Fan Out Wafer Level Package (FOWLP) will be described with reference to FIG. 5. FIG. 5 is a schematic view showing the sectional structure of the semiconductor device 300 in the FOWLP form. A redistribution layer (RDL) 301 is arranged on the lower side of the structure 152 (on the side opposite to the structure 153), and connects elements, circuits, and the like arranged in the structures 151 and 153 to external terminals.

The arrangement shown in FIG. 5 shows a case where the structure 151, the structure 152, and the structure 153 are different in size in the orthogonal projection with respect to the bonding surface BS1. For example, the structure 151 and the structure 153 are bonded by direct bonding in which the structure 151 separated into individual pieces are tiled on the bonding surface BS1 of the structure 153. The structure 152 and the structure 153 are bonded by flip-chip bonding. In flip-chip bonding, a space between bumps is usually filled with a filler such as a resin. Many resins have a low thermal conductivity. Thus, unlike the direct bonding between the structure 151 and the structure 153, the amount of heat transferred from the structure 152 to the structure 153 relatively decreases. The layer where the bumps and filler are arranged can correspond to the thermal insulating layer described above. Further, an additional thermal insulating layer or the above-described heat storage layer may be provided. This makes it difficult for the heat generated in the control circuit or the like arranged in the structure 152 to be transmitted to the structure 153. As a result, the heat generated in the structure 151 is more efficiently transmitted to the structure 153.

The method and form of bonding the structure 151 and the structure 153 and those of bonding of the structure 153 and the structure 152 are merely examples for explaining this embodiment. The stacking form in the semiconductor device 300 is not limited to the form described above, and any appropriate method and form may be used.

A dielectric layer 302 using a resin or the like serving as a dielectric is arranged around the structure 152 so as to be embedded in the structure 153. In the dielectric layer 302, a conductor plug 303 that electrically and thermally connects the structure 153 to the redistribution layer 301 is provided. For the conductor plug 303, a copper pillar for interconnection may be used but is not limited thereto. A terminal 310 for connecting the semiconductor device 300 to an external substrate is arranged under the redistribution layer 301. The terminal 310 can be provided with a solder bump 304. In the redistribution layer 301, electrical paths are arranged to connect elements, circuits, and the like arranged in the structures 151 and 152 to external circuits and the like. Passive components (not shown) such as filters and capacitors necessary for signal control for driving the semiconductor device 300 may be arranged inside or on the surface of the redistribution layer 301, as appropriate.

The semiconductor device 300 may be embedded in a sealing resin 305 to seal the entire semiconductor device 300 in accordance with the size of the redistribution layer 301. Since a terahertz wave is emitted/received from/by the surface of the structure 151, it is necessary to select a material for the sealing resin 305 that transmits the terahertz wave in the frequency band to be emitted or detected by the semiconductor device 300. Alternatively, the sealing resin 305 may not be arranged on the upper surface of the structure 151. Alternatively, for example, the material of the sealing resin 305 may be different between the portion arranged on the upper surface of the structure 151 and other portions. Alternatively, for example, the sealing resin 305 may not be arranged on the upper surface of the structure 151, and sealing may be performed using glass or the like.

In the semiconductor device 300, two main paths for dissipating the heat in the structures 151, 153, and 152 to the outside are arranged. The first path is a path for releasing the heat of the structure 151. As in the embodiment described above, the heat of the structure 151 is transmitted to the structure 153 having a high thermal conductivity, and transferred to the outer peripheral portion 166 of the structure 153. The heat transferred to the outer peripheral portion 166 of the structure 153 is transmitted to the redistribution layer 301 by a conductor plug 306 for thermal conduction provided in the dielectric layer 302 arranged so as to surround the structure 152. The conductor plug 306 for thermal conduction may have a structure similar to that of the conductor plug 303, but to increase the thermal conductivity, the conductor plug 306 may be thicker than the conductor plug 303 as shown in FIG. 5, or more conductor plugs 306 may be arranged. In the redistribution layer 301, the heat is further transmitted to the solder bump 304 by the wiring pattern and a conductor plug 307 considering the thermal conduction, and is dissipated to the outside of the semiconductor device 300.

The second path is a path for releasing the heat of the structure 152. In the semiconductor device 300 formed to reduce heat transfer between the structure 153 and the structure 152, the structure 152 is configured to take a heat dissipation path from the lower surface (the surface opposite to the structure 153). A layer using a material having a high thermal conductivity, such as a metal layer 309, is arranged on the lower surface of the structure 152. The metal layer 309 is connected to a conductor plug 308 for thermal conduction, thereby dissipating the heat to the outside via the solder bump 304. Alternatively, instead of the solder bump 304, a heat dissipation terminal formed larger than the terminal 310 may be provided on the lower surface of the redistribution layer 301 in a region overlapping the conductor plug 308, and the heat dissipation terminal and an external printed board or the like may be directly soldered.

In the semiconductor device 300 that emits or detects a terahertz wave band as shown in FIG. 5, a signal from outside the semiconductor device 300 is connected by the solder bump 304. With this, the influence of impedance caused by wiring such as a bonding wire can be significantly reduced. Hence, the stability of signal transmission in the high frequency region is improved, which can contribute to stabilizing the operation and improving the performance of the semiconductor device 300.

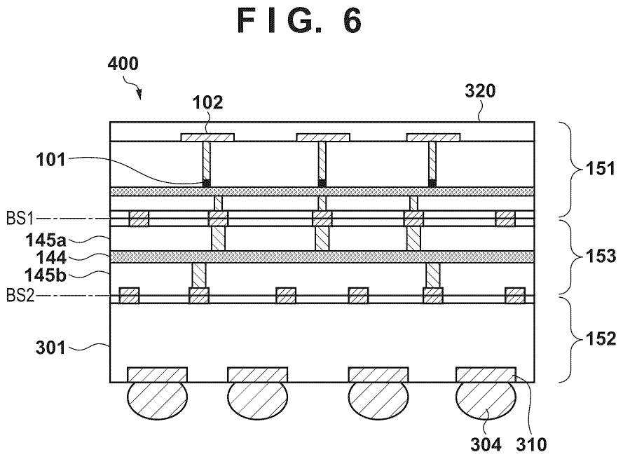

FIG. 6 is a schematic view showing the sectional structure of a semiconductor device 400 packaged in a Wafer Level Chip Size Package (WLCSP) form. In the arrangement shown in FIG. 6, the structures 151, 153, and 152 can be formed by a processing process in which the structures are bonded in a state of wafers. Finally, the redistribution layer 301 is bonded to the lower surface of the structure 152, and the solder bump 304 is arranged on the terminal 310. After undergoing a series of steps such as inspection, dicing is performed to separate the semiconductor device 400 into individual pieces. The redistribution layer 301 bonded to the structure 152 electrically connects the control circuit and the like arranged in the structure 152 to the terminals 310. The redistribution layer 301 may be provided with a buffer layer that mitigates the influence of expansion/contraction caused by a temperature change upon mechanical connection to a mounting substrate such as a printed board on which the semiconductor device 400 is mounted.

A protection layer 320 is provided on a portion of the upper surface of the structure 151 where the conductor pattern 102 serving as the antenna for emitting or detecting a terahertz wave is arranged. The protection layer 320 may be arranged on the dielectric layer 112 described above, or the dielectric layer 112 may be used as the protection layer 320. For the protection layer 320, a material that transmits a terahertz wave in the frequency band to be oscillated or detected and has a low dielectric loss can be used. Since a conductor such as a metal does not transmit a terahertz wave, a material having a low thermal conductivity such as glass or a resin is used for the protection layer 320. Therefore, it is difficult to efficiently dissipate the heat generated in the semiconductor element 101 or the like arranged in the structure 151 from the upper surface of the structure 151. However, by using the structure 153 having a high thermal conductivity as described above, the heat generated in the structure 151 can be efficiently transferred to the outside.

The outer edge of structure 153 is thermally exposed at the side wall of semiconductor device 400. For example, the outer edge of the structure 153 may be in contact with a thermal conductive component made of a metal or the like arranged outside the semiconductor device 400. With this, the heat generated in the semiconductor element 101 can be efficiently dissipated to the outside of the semiconductor device 400. Also in this embodiment, the semiconductor device 400 can shorten the electrical path between the mounting substrate such as a printed board, on which the semiconductor device 400 is mounted, and the structures 152 and 151 in the semiconductor device 400. Hence, the influence of impedance on a high frequency signal according to packaging is suppressed and the stability of signal transmission in the high frequency region is improved, which can contribute to stabilizing the operation and improving the performance of the semiconductor device 400.

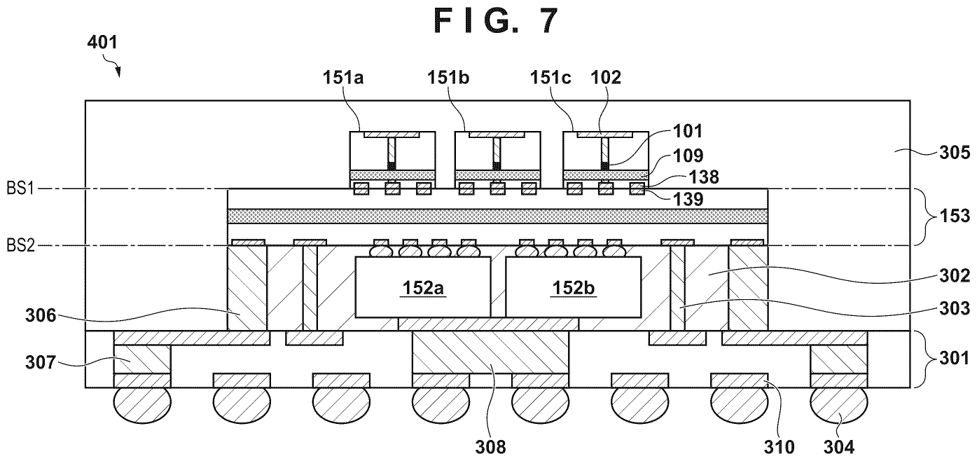

FIG. 7 shows a semiconductor device 401 as a modification of the semiconductor device 300 shown in FIG. 5. The semiconductor device 401 is a package in the same FOWLP form as the semiconductor device 300, but includes a structure 151a, a structure 151b, and a structure 151c as the structure 151. Each of the structures 151a to 151c includes the conductor pattern 102 arranged on the upper surface of the structure and serving as the antenna for emitting or detecting a terahertz wave, the semiconductor element 101, and the conductor layer 109 serving as a GND layer. Each of the structures 151a to 151c may be arranged with one active antenna AA as shown in FIG. 7, but the present invention is not limited to this. The active antenna array 11 including the plurality of active antennas AA as described above may be arranged in each of the structures 151a to 151c. The number of the structures 151 and the number of the active antennas AA arranged in each structure 151 may be decided based on the optimum shape that can be manufactured while considering constraints on the tiling position and the antenna arrangement.

Here, in the region where the plurality of structures 151 are arranged on the structure 153, a structure different from the structure 151, for example, a structure in which the antenna and semiconductor element for oscillating or detecting a terahertz wave are not arranged may be arranged. For example, a circuit such as an amplifier or a mixer for processing a high frequency signal may be arranged in the structure different from the structure 151. Further, passive elements such as a resistor and a capacitor may be arranged in the region around the structure 151. A method such as tiling can be used to bond the structures 151a to 151c and the structure 153, and the plurality of structures 151a to 151c separated into individual pieces can be directly bonded to the structure 153 so as to be electrically coupled to the electrode patterns 139 of the structure 153. However, the present invention is not limited to this, and the structures 151a to 151c and the structure 153 may be connected by an appropriate method.

In the arrangement shown in FIG. 7, similar to the structures 151a to 151c, a plurality of structures 152a and 152b are arranged. Each of the structures 152a and 152b is an integrated circuit board including a control circuit for controlling the active antenna AA, or the like. For example, different structures 152a and 152b may be used for each region of the active antenna array 11 so as to control the structure 151 immediately above, or the like. Alternatively, the structures 152a and 152b may have circuit configurations separated by function such that, for example, the structure 152a includes a control circuit for oscillating a terahertz wave, and the structure 152b includes a control circuit for detecting a terahertz wave. The structures 152a and 152b and the structure 153 are bonded by flip-chip bonding as in the above description, and the bonded portion is sealed with the dielectric layer 302 made of a resin or the like called a filler. The arrangement of the redistribution layer 301 and the like may be similar to that of the semiconductor device 300 described above, so that the description thereof will be omitted here.

The semiconductor element 101 for emitting or detecting an electromagnetic wave in a frequency band of a terahertz wave or the like requires high-frequency signal transmission. Therefore, in many cases, a group III-V compound semiconductor such as InP is used instead of an inexpensive Si-based semiconductor. Since a compound semiconductor substrate is expensive, the cost can be reduced by cutting it into small pieces. Furthermore, by performing packaging while embedding a plurality of control ICs (structures 152) in the dielectric layer 302 for the structure 153 serving as the interposer board, like the plurality of structures 152a and 152b, the completed semiconductor device 401 can achieve both high functionality and miniaturization.

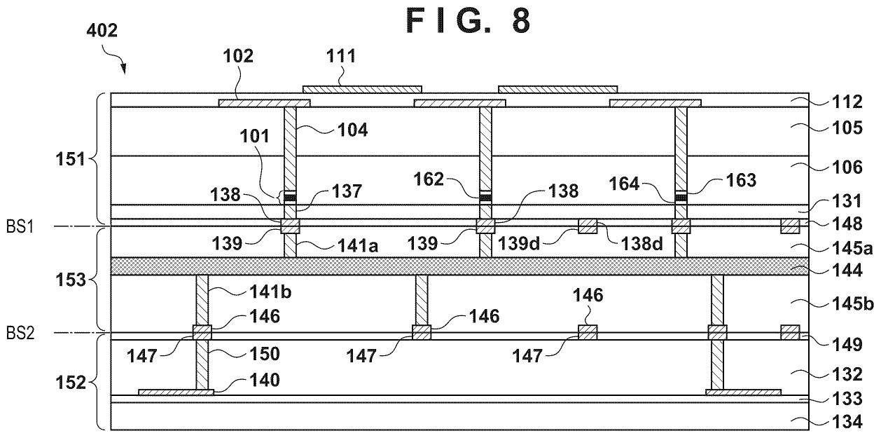

FIG. 8 is a schematic view showing the sectional structure of a semiconductor device 402 as a modification of the semiconductor device 100 described above. In the semiconductor device 402, the conductor layer 109 is not arranged, and the conductor layer 144 of the structure 153 is used as a reflector layer of the active antenna AA. The semiconductor element 101 is arranged between the conductor layer 144 serving as the reflector and the conductor pattern 102 serving as the antenna, and these components form the active antenna AA.

In the structure 153 of the semiconductor device 402, since the conductor layer 144 serves as the reflector, the thickness of the base material layer 145a may be decreased and the thickness of the base material layer 145b may be increased as compared to the semiconductor device 100. More specifically, the thickness of the base material layer 145a is set to 10 μm or less, and the thickness of the base material layer 145b is set to 200 μm or more. With this, the conductor layer 144 can serve as the reflector layer in the antenna of the structure 151 while suppressing the influence of noise from the control circuit or the like arranged in the structure 152. Further, in the semiconductor device 402, the conductor plug 137 and the electrode pattern 138 are provided so as to overlap the semiconductor element 101 in the orthogonal projection with respect to the bonding surface BS1, thereby linearly connecting the semiconductor element 101 to the structure 153. This arrangement is intended to reduce the thermal resistance between the semiconductor element 101 and the structure 153 as much as possible. Depending on the manufacturing method, a form is also possible in which the semiconductor element 101 is directly connected to the electrode pattern 138 without intervening the conductor plug 137.

The arrangement shown in the semiconductor device 402 can shorten the distance from the semiconductor element 101 to the structure 153. Then, the heat generated during driving of the semiconductor element 101 is easily propagated to the structure 153 even in a portion where no conductor such as the conductor plug 137 is arranged. That is, the semiconductor device 402 can dissipate heat more efficiently than the semiconductor device 100.

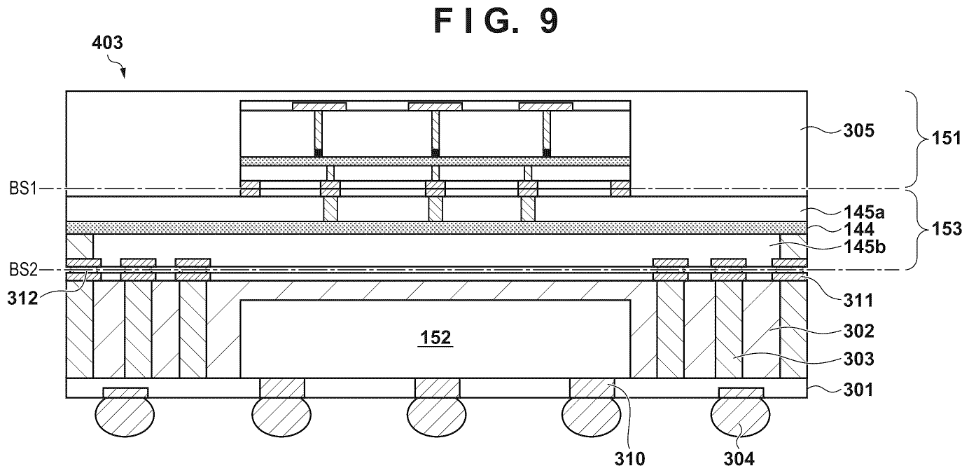

FIG. 9 shows a semiconductor device 403 in a flip-chip Package On Package (POP) form. The structure 151 serving as the antenna board and the structure 153 serving as the interposer board are bonded via the bonding surface BS1 of the structure 153 and integrated as one package. By arranging the sealing resin 305 around the structure 151, a package form that fits the shape of the structure 153 serving as the interposer is obtained. A terminal 312 made of a metal such as gold (Au) is arranged on the bonding surface BS2 of the structure 153 to electrically connect with the structure 151.

On the other hand, in the structure 152 serving as the integrated circuit board, the redistribution layer 301 is bonded to the surface opposite to the surface facing the structure 153. The structure 152 is embedded in the dielectric layer 302 using a resin or the like, and the dielectric layer 302 expands the structure 152 to the size of the redistribution layer. Further, the conductor plug 303 extending through the dielectric layer 302 is arranged in the dielectric layer 302. The conductor plug 303 may be a metal structure such as a copper pillar. The conductor plug 303 is electrically connected to the redistribution layer 301. A solder bump 304 is arranged on the lower surface of the redistribution layer 301 and connected to a mounting substrate such as a printed board on which the semiconductor device 403 is mounted. A terminal 311 electrically connected to the conductor plug 303 arranged in the dielectric layer 302 is arranged in a portion of the dielectric layer 302 facing the bonding surface BS2 of the structure 153. The terminal 311 is electrically connected to the terminal 312 arranged on the bonding surface BS2 of the structure 153 by flip-chip bonding. By connecting the terminal 311 and the terminal 312, a control signal output from the control circuit 165 or the like of the structure 152 is sent to the structure 151. A region of the bonding surface BS2 of the structure 153 where the terminal 312 does not exist serves as the thermal insulating layer described above which suppresses transmission of the heat of the structure 152 to the structure 153, if the region is an air layer physically separated from the dielectric layer 302. Alternatively, the space between the structure 152 and the structure 153 may be filled with a resin or the like to prevent deterioration such as corrosion. Even in that case, heat propagation is suppressed because the resin has a low thermal conductivity. Alternatively, for example, a layer of a ceramic having a large heat capacity (specific heat) or a resin such as silicone may be arranged as a heat storage layer between the structure 152 and the structure 153 to control the temperature of the semiconductor device 403 so as not to excessively drop due to heat dissipation.

In the semiconductor device 403, the structure 151 and the structure 153 are formed as one package, the structure 152 is formed as another package, and these packages are bonded by flip-chip bonding, thereby stacking three structures. Even if the specification such as the frequency of a terahertz wave to be emitted by the structure 151 is changed and the size of the antenna or the size of the substrate is changed accordingly, changes in the specifications of the structure 152 can be minimized. In addition, since heat is not easily transmitted between the structure 152 and the structure 153, the heat generated in the structure 151 can be efficiently transmitted to the outside of the semiconductor device 403 via the structure 153.

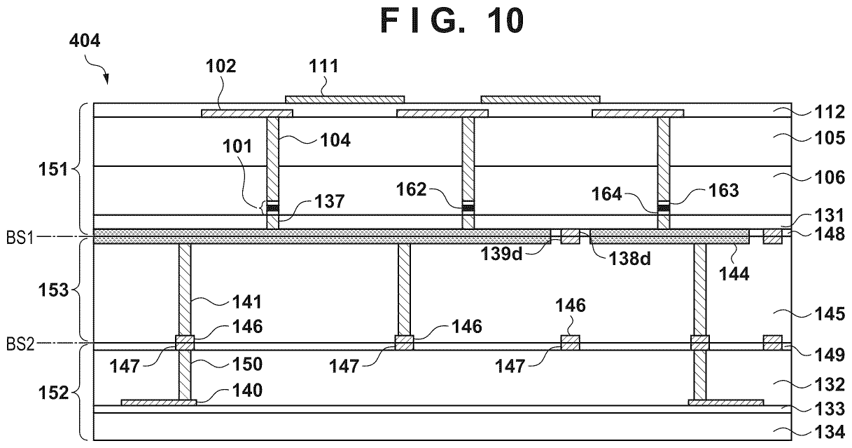

FIG. 10 is a schematic view showing the sectional structure of a semiconductor device 404 as a modification of the semiconductor device 402. In the semiconductor device 404, at least a part of the bonding surface BS1 of the structure 153 is formed by the conductor layer 144. Further, the base material layer 145 is one layer between the conductor layer 144 and the structure 152. The structure 151 and the structure 153 may be bonded by metal bonding such as Cu—Cu bonding between a conductor layer arranged in the same layer as the electrode pattern 138 and the conductor layer 144. The above-described electrode pattern 139 can be arranged in the same layer as the conductor layer 144. Accordingly, the arrangement of the semiconductor device 404 can simplify the structure of the structure 153. As has been described above, if the conductor plug 137 and the electrode pattern 138 are defined as a conductor plug as one member arranged in the structure 151, it can also be said that this conductor plug is in contact with the conductor layer 144 exposed at the bonding surface BS1.

The structure 153 can be created by, in the base material layer 145 as one base material, forming the conductor layer 144 and the electrode pattern 139 formed from one conductor layer, forming the conductor plug 141 extending through the base material layer 145, and forming the electrode pattern 146 on the bonding surface BS2. A conductor layer may be formed on the bonding surface BS2 and metal bonding with the structure 152 may be performed.

As in the semiconductor device 402, in the semiconductor device 404, the conductor layer 109 is not arranged in the structure 151. With this, the distance between the conductor pattern 102 serving as the upper conductor of the antenna in the structure 151 and the conductor layer 144 serving as the reflector layer can be made larger than in the semiconductor device 100. By appropriately setting the distance between the upper conductor and the reflector layer, it is possible to optimize a conductor loss due to terahertz wave resonance and an improvement of the radiation efficiency of the antenna. Further, since the distance between the semiconductor element 101 and the structure 153 is short, highly efficient heat dissipation is possible as in the semiconductor device 402.

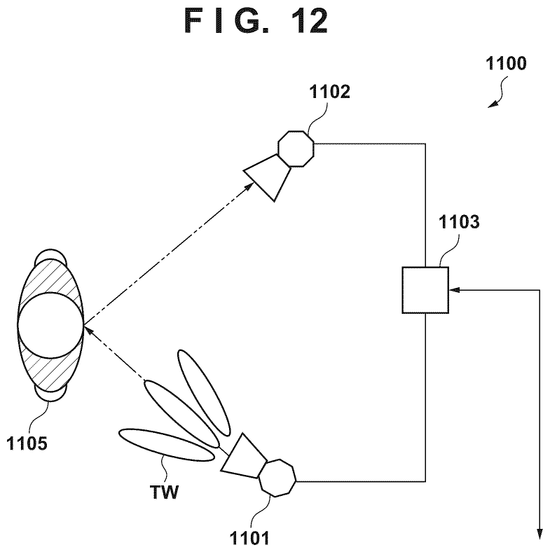

Next, with reference to FIG. 12, a case where the semiconductor devices 100, 300, and 400 to 404 described above are applied to a terahertz camera system (image capturing system) will be described. A terahertz camera system 1100 includes a transmission unit 1101 that emits a terahertz wave TW, and a reception unit (detection unit) 1102 that detects the terahertz wave TW. The terahertz camera system 1100 further includes a control unit 1103 that controls the operations of the transmission unit 1101 and the reception unit 1102 based on an external signal, processes an image based on the detected terahertz wave, or outputs an image to the outside. The above-described semiconductor devices 100, 300, and 400 to 404 may be used as the transmission unit 1101, or the above-described semiconductor devices 100, 300, and 400 to 404 may be used as the reception unit 1102.

The terahertz wave TW emitted from the transmission unit 1101 is reflected by an object 1105, and detected by the reception unit 1102. The camera system including the transmission unit 1101 and the reception unit 1102 can also be called an active camera system. Note that even in a passive camera system that does not include the transmission unit 1101 and detects a terahertz wave emitted by the object 1105, the above-described semiconductor devices 100, 300, and 400 to 404 can be used as the reception unit 1102. As has been described above, by appropriately arranging any of the semiconductor devices 100, 300, and 400 to 404 with good heat dissipation efficiency in the system, a stable terahertz wave transmission or detection operation can be performed.

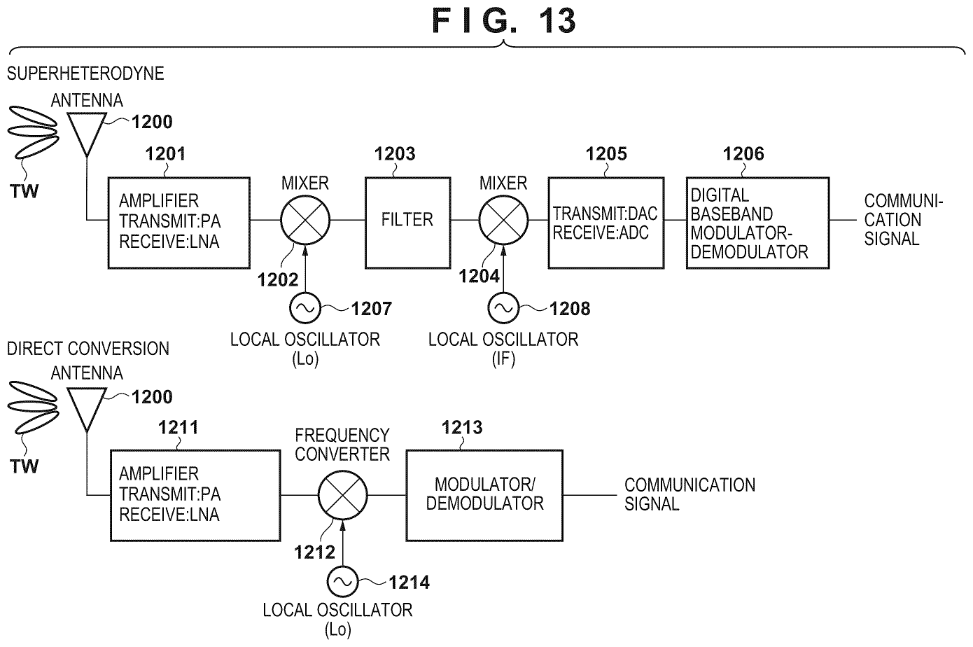

Next, with reference to FIG. 13, a case where the semiconductor devices 100, 300, and 400 to 404 described above are applied to a terahertz communication system (communication apparatus) will be described. As the communication system, a configuration such as a superheterodyne method or a direct conversion method using a simple ASK modulation method or the like is assumed. The communication system using the superheterodyne method includes, for example, an antenna 1200, an amplifier 1201, a mixer 1202, a filter 1203, a mixer 1204, a converter 1205, a digital baseband modulator-demodulator 1206, and local oscillators 1207 and 1208. In the case of a receiver, a terahertz wave TW received via the antenna 1200 is converted into a signal of an intermediate frequency by the mixer 1202, and is then converted into a baseband signal by the mixer 1204, and an analog waveform is converted into a digital waveform by the converter 1205. After that, the digital waveform is demodulated in the baseband to obtain a communication signal. In the case of a transmitter, after a communication signal is modulated, the communication signal is converted from a digital waveform into an analog waveform by the converter 1205, is frequency-converted via the mixers 1204 and 1202, and is then output as a terahertz wave from the antenna 1200. The communication system using the direct conversion method includes the antenna 1200, an amplifier 1211, a mixer 1212, a modulator-demodulator 1213, and a local oscillator 1214. In the direct conversion method, the mixer 1212 directly converts the received terahertz wave into a baseband signal at the time of reception, and the mixer 1212 converts the baseband signal to be transmitted into a signal in a terahertz band at the time of transmission. The remaining components are the same as those in the superheterodyne method.

Each of the semiconductor devices 100, 300, and 400 to 404 can serve as the antenna 1200 or the local oscillator (1207 or 1214) of the communication system, and the oscillation portion of the upper conductor of the antenna can serve as the mixer (1202 or 1212). By integrating other elements in the structure 151 and using the Si integrated circuit of the structure 152, all the processing units used for communication signal conversion shown in FIG. 13 can be integrated in each of the semiconductor devices 100, 300, and 400 to 404. Accordingly, this can be used as a small integrated IC for communication system. Further, since heat can be dissipated efficiently, stable driving can be achieved even under a severe driving condition such as continuous high-speed, large-capacity wireless communication using communication equipment.

The embodiments of the present invention have been described above. However, the present invention is not limited to these embodiments and various modifications and changes can be made within the spirit and scope of the present invention.

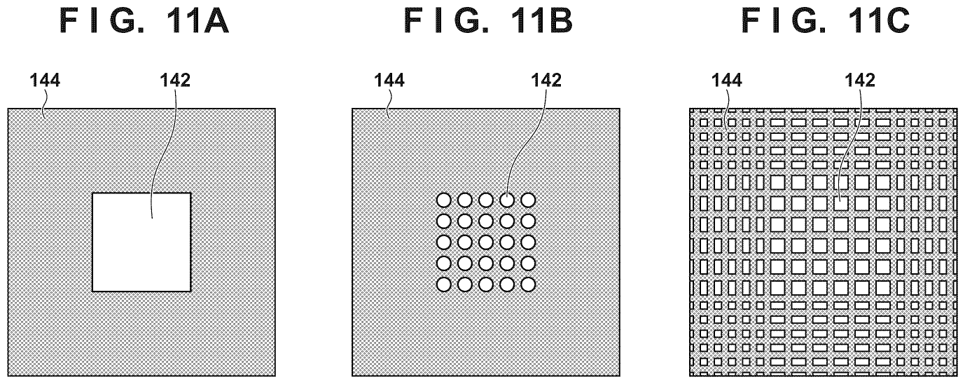

For example, each of FIGS. 11A to 11C shows the layout of the conductor pattern of the conductor layer 144 in the structure 153. The region 167 overlapping the active antenna array 11 exists in the central portion of the conductor layer 144, and the electrical paths such as the conductor pattern 143 connected to the plurality of conductor plugs 141 pass therethrough. In the arrangement shown in FIG. 11A, the opening portion 142 is arranged as one large pattern in the central portion of the conductor layer 144. In FIGS. 11A to 11C, the conductor pattern 143 is not shown. The heat transferred from the structure 151 passes through the base material layer 145 of the structure 153, and part of the heat propagates to the conductor layer 144 and is transmitted to the outer edge of the structure 153. In the arrangement shown in FIG. 11B, the opening portion 142 is provided so as to correspond to each conductor pattern 143 connected to the conductor plug 141. Further, in the arrangement shown in FIG. 11C, the conductor layer 144 is arranged in a mesh shape, and gaps in the mesh are used as the opening portions 142. Each of these layout patterns of the conductor layer 144 is intended to provide the structure 153 serving as the interposer board with a function of electrically connecting the structure 151 and the structure 152 and a function of efficiently dissipating heat to the outer edge of the structure 153. The layout pattern of the conductor layer 144 is not limited to the patterns described above, and an appropriate shape may be used in accordance with these functions.

Each of the above-described embodiments assumes that carriers are electrons. However, the present invention is not limited to this and holes may be used. Furthermore, the materials of the substrate and the dielectric are selected in accordance with an application purpose, and a semiconductor layer of silicon, gallium arsenide, indium arsenide, gallium phosphide, or the like, glass, a ceramic, and a resin such as polytetrafluoroethylene or polyethylene terephthalate can be used.

Furthermore, as the semiconductor element 101, a Quantum Cascade Laser (QCL) having a semiconductor multilayer structure of several hundred to several thousand layers may be used. In this case, the semiconductor element 101 is a semiconductor element including the QCL structure. As the semiconductor element 101, a negative resistance element such as a Gunn diode or IMPATT diode used in the millimeter wave band may be used. As the semiconductor element 101, a high frequency element such as a transistor with one terminal terminated may be used. A heterojunction bipolar transistor (HBT), a compound semiconductor FET, a high electron mobility transistor (HEMT), or the like may be used as the transistor. As the semiconductor element 101, a negative differential resistance of the Josephson device using a superconductor layer may be used.

The relationship between the active antenna array 11 and the control circuit 165 shown in FIG. 3A may be in the following form. The active antenna array 11 includes the plurality of active antennas AA, and the control circuit 165 includes the plurality of control elements AC. Each of the plurality of active antennas AA may be controlled by a signal from each of the plurality of control elements AC. That is, one control element AC may control one active antenna AA. It is possible to increase the degree of freedom of control of the antenna.

Furthermore, the plurality of control elements AC may control one active antenna AA. In this case, the degree of freedom of the operation can be increased. For example, each active antenna AA is controlled at each timing, or a plurality of active antennas AA are controlled at each timing. If a complicated operation is performed, the above connection methods can arbitrarily be combined.

In this embodiment, the structure 151 having a function of emitting or detecting an electromagnetic wave in a terahertz band has been described. However, the electromagnetic wave supported by the structure 151 to which the present disclosure is applied is not limited to this. The structure 151 may be used to emit or detect an electromagnetic wave such as a microwave, a millimeter wave, or an infrared ray. Further, the stacked device structure including the structure 153 described above is also applicable in a semiconductor device using a semiconductor element such as a CMOS image sensor or a single photon avalanche diode (SPAD) sensor.

According to the present invention, a technique advantageous in suppressing temperature rise of a device can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-078703, filed May 11, 2023, which is hereby incorporated by reference herein in its entirety.

What is claimed is:

1. A semiconductor device in which a first structure that includes a first semiconductor substrate on which a semiconductor element and an antenna configured to oscillate or receive an electromagnetic wave are arranged, a second structure that includes a second semiconductor substrate on which a control circuit configured to control the semiconductor element is arranged, and a third structure that has a first bonding surface bonded to the first structure and a second bonding surface bonded to the second structure are stacked, wherein
a first conductor plug electrically connected to the semiconductor element and reaching the first bonding surface is arranged in the first structure,
the third structure includes a base material layer and a conductor layer stacked on each other, and
the third structure has a higher thermal conductivity than the first structure and the second structure.

2. The device according to claim 1, wherein
the electromagnetic wave includes a terahertz wave.

3. The device according to claim 1, wherein
a thickness of the third structure is thicker than a thickness of the first semiconductor substrate.

4. The device according to claim 1, wherein
a thickness of the third structure is not less than 100 μm and not more than 1 mm.

5. The device according to claim 1, wherein
the base material layer contains a ceramic.

6. The device according to claim 1, wherein
the base material layer contains at least one of aluminum nitride and graphite.

7. The device according to claim 1, wherein
the thermal conductivity of the third structure is not less than 100 W/m·K.

8. The device according to claim 1, wherein
the base material layer includes a first base material layer arranged between the first structure and the conductor layer, and a second base material layer arranged between the conductor layer and the second structure.

9. The device according to claim 8, wherein
the first conductor plug extends through the first base material layer and is electrically connected to the conductor layer.

10. The device according to claim 1, wherein
the first structure comprises an active antenna array where a plurality of active antennas each including the semiconductor element and the antenna are arranged.

11. The device according to claim 1, wherein
the first structure includes a first wiring layer and a second wiring layer arranged between the first wiring layer and the third structure,
the antenna includes a first conductor pattern arranged in the first wiring layer and electrically connected to the semiconductor element, and
a second conductor pattern having a larger area than the first conductor pattern in an orthogonal projection with respect to the first bonding surface and electrically connected to the semiconductor element is arranged in the second wiring layer.

12. The device according to claim 1, wherein
in a thermal equilibrium state during operation of the semiconductor device, a temperature of the third structure has a gradient that decreases from a center of the third structure toward an outer edge in an orthogonal projection with respect to the first bonding surface.

13. The device according to claim 1, wherein
a thermal insulating layer having a thermal conductivity of less than 1 W/m·K is arranged between the second semiconductor substrate and the third structure.

14. The device according to claim 1, wherein
a heat storage layer having a specific heat of not less than 0.9 kJ/kg·K is arranged in at least one of the first semiconductor substrate and the second semiconductor substrate.

15. The device according to claim 1, wherein
a heat dissipator using a conductor and in contact with an outer edge of the third structure is arranged.

16. The device according to claim 15, further comprising a support substrate,
wherein the second structure is arranged between the support substrate and the third structure, and
the heat dissipator is fixed to the support substrate and arranged closer on a side of the support substrate than the antenna.

17. The device according to claim 1, wherein
the semiconductor element includes a negative resistance element.

18. The device according to claim 17, wherein
the negative resistance element includes a resonant tunneling diode.

19. A communication apparatus comprising:
the semiconductor device according to claim 1;
a transmitter configured to emit the electromagnetic wave; and
a receiver configured to detect the electromagnetic wave.

20. An image capturing system comprising:
the semiconductor device according to claim 1; and
a detector configured to detect an electromagnetic wave reflected or emitted by an object.
